(19) United States
(12) Patent Application Publication
(10) Pub. No.: US 2024/0379609 A1
(43) Pub. Date: Nov. 14, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wei-Shen HUNG, Taichung City (TW); Hsuan-Jen WANG, Taichung City (TW); Rung-Jeng LIN, Taichung City (TW)

(21) Appl. No.: 18/357,459

(22) Filed: Jul. 24, 2023

(30) Foreign Application Priority Data
May 11, 2023 (TW) 112117567

(51) Int. Cl. H01L 23/00; H01L 21/48; H01L 21/56; H01L 23/31; H01L 23/367

(52) U.S. Cl. CPC H01L 24/32; H01L 21/4882; H01L 21/56; H01L 23/3107; H01L 23/3675; H01L 24/16; H01L 24/73; H01L 2224/16225; H01L 2224/26175; H01L 2224/32225; H01L 2224/32245; H01L 2224/73204; H01L 2224/73253; H01L 2924/16153; H01L 2924/16235; H01L 2924/16251; H01L 2924/1632; H01L 2924/172; H01L 2924/3511

(57) ABSTRACT

An electronic package and a manufacturing method thereof are provided, in which a dam is surrounding an electronic component on a carrier structure, the electronic component is encapsulated by a thermal conduction layer, and the electronic component, the dam and the thermal conduction layer are covered by a heat sink, such that the dam strongly supports the heat sink to effectively disperse the thermal stress, so as to effectively control the warpage of the heat sink to prevent the problem of delamination from occurring between the heat sink and the thermal conduction layer.

### BACKGROUND

### 1. Technical Field

The present disclosure relates to a semiconductor packaging process, and more particularly, to an electronic package with a heat dissipation structure and a manufacturing method thereof.

### 2. Description of Related Art

With the improvement of functions and processing speed of electronic products,

semiconductor chips as core components of the electronic products need to have higher density electronic components and electronic circuits, so the semiconductor chips will generate large amount of heat during the operation. Further, due to that the conventional encapsulation colloid encapsulating the semiconductor chip is made of a poor heat transfer material with a thermal conductivity of only 0.8 W·m⁻¹·k⁻¹ (i.e., the heat dissipation efficiency is poor), so if the heat generated from the semiconductor chip cannot be effectively dispersed, it will cause problems of damage to the semiconductor chip and product reliability.

In order to disperse the heat outside, a heat sink or a heat spreader is usually configured in a semiconductor package in the industry. The heat sink is bonded to the back of the semiconductor chip by a heat dissipation glue such as a thermal interface material (TIM), and the top surface of the heat sink is exposed from an encapsulation colloid or directly exposed to the atmosphere, so that the heat generated from the semiconductor chip can be dispersed by the heat dissipation glue and the heat sink.

As shown in FIG. 1, in a conventional semiconductor package 1, a semiconductor chip 11 is firstly disposed on a package substrate 10 with an active surface 11a of the semiconductor chip 11 by means of flip-chip bonding (i.e., via conductive bumps 110 and an underfill 111), then a heat sink 13 is bonded on an inactive surface 11b of the semiconductor chip 11 with a top sheet 130 of the heat sink 13 by a TIM layer 12, and supporting legs 131 of the heat sink 13 are erected on the package substrate 10 via an adhesive layer 14. Next, a packaging molding operation is carried out for an encapsulation colloid (not shown) to encapsulate the semiconductor chip 11 and the heat sink 13, and the top sheet 130 of the heat sink 13 is exposed from the encapsulation colloid.

During the operation, heat generated from the semiconductor chip 11 is transferred to the top sheet 130 of the heat sink 13 via the inactive surface 11b and the TIM layer 12, so that the heat can be dispersed to the outside of the semiconductor package 1.

Moreover, in the manufacturing process of the conventional semiconductor package 1, the supporting legs 131 of the heat sink 13 are directly pasted after the adhesive layer 14 is heated and glued on the package substrate 10, and the adhesive force is generated after the adhesive layer 14 is cooled, so that the package substrate 10 and the heat sink 13 are bonded together.

However, in the conventional semiconductor package 1, under the requirements of thinning and increasing board area, deformation (i.e., the extent of warping) between the heat sink 13 (or the semiconductor chip 11) and the TIM layer 12 becomes more apparent due to the mismatch of the coefficient of thermal expansion (CTE). When there is too much deformation, delamination is likely to occur between the top sheet 130 of the heat sink 13 (or the semiconductor chip 11) and the TIM layer 12, which not only causes the thermal conduction effect to decrease, but also causes the poor appearance of the semiconductor package 1 and even seriously affects the reliability of products.

Therefore, how to overcome the problems of the above-mentioned prior art has become an urgent problem to be solved at present.

### SUMMARY

In view of the aforementioned shortcomings of the prior art, the present disclosure provides an electronic package, which comprises: a carrier structure; an electronic component disposed on the carrier structure; a dam disposed on the carrier structure and surrounding the electronic component; a thermal conduction layer encapsulating the electronic component and located between the electronic component and the dam; and a heat sink disposed on the carrier structure and covering the electronic component, the dam and the thermal conduction layer, wherein the thermal conduction layer is further located between the heat sink and the electronic component.

The present disclosure also provides a method of manufacturing an electronic package, the method comprises: disposing an electronic component on a carrier structure; disposing a dam on the carrier structure; encapsulating the electronic component by a thermal conduction layer; and disposing a heat sink on the carrier structure to cover the electronic component, the dam and the thermal conduction layer, wherein the electronic component is surrounded by the dam, and the thermal conduction layer is located between the electronic component and the dam and between the heat sink and the electronic component.

In the aforementioned electronic package and method, the dam is a wall structure.

In the aforementioned electronic package and method, the dam is a frame.

In the aforementioned electronic package and method, the dam is made of an insulating material or a metal material.

In the aforementioned electronic package and method, the dam and the heat sink are integrally formed.

In the aforementioned electronic package and method, the dam is bonded to the heat sink via an adhesive material.

In the aforementioned electronic package and method, the thermal conduction layer is made of a liquid metal.

In the aforementioned electronic package and method, the heat sink has a heat dissipation body bonded to the thermal conduction layer and the dam and has a plurality of supporting legs disposed on the heat dissipation body and bonded to the carrier structure. For instance, the heat dissipation body and the supporting legs are integrally formed. Alternatively, the heat dissipation body is bonded to the supporting legs via an adhesive material.

It can be seen from the above that in the electronic package and the manufacturing method thereof according to the present disclosure, the arrangement of the dam can strongly support the heat sink, so that the thermal stress can be effectively dispersed, thereby effectively controlling the deformation (the warpage) of the electronic component and/or the heat dissipation body. Hence, compared to the prior art, the electronic package of the present disclosure not only can meet the requirements of thinning and increasing board area, but also can prevent the electronic component or the heat sink from excessive warping due to stress concentration, so as to prevent the problem of delamination from occurring between the electronic component (and/or the heat dissipation body) and the thermal conduction layer.

### BRIEF DESCRIPTION OF THE DRAWINGS

FIG. 1 is a schematic cross-sectional view of a conventional semiconductor package.

FIG. 2A-1, FIG. 2B, FIG. 2C and FIG. 2D are schematic cross-sectional views illustrating a method of manufacturing an electronic package according to the present disclosure.

FIG. 2A-2 is a schematic top view of FIG. 2A-1.

FIG. 3 is a schematic cross-sectional view showing another embodiment of FIG. 2D.

FIG. 4 is a schematic cross-sectional view showing another embodiment of FIG. 3.

FIG. 5 is a schematic cross-sectional view showing another embodiment of FIG. 4.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

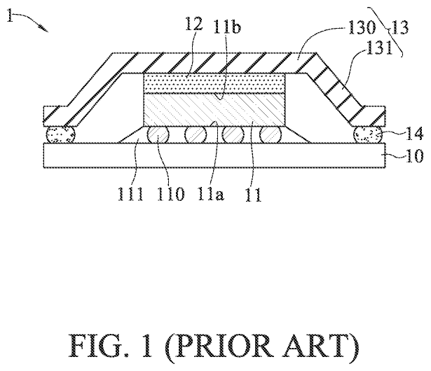

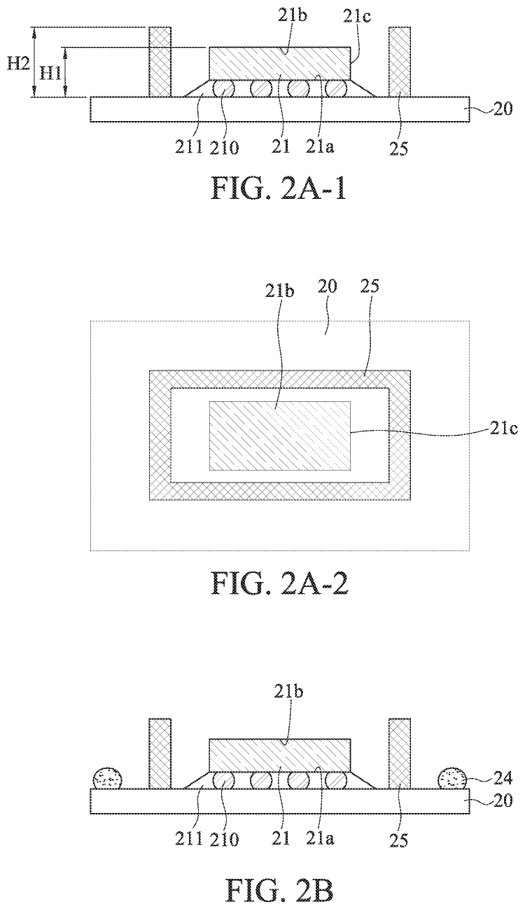

FIG. 2A-1, FIG. 2B, FIG. 2C and FIG. 2D are schematic cross-sectional views illustrating a method of manufacturing an electronic package 2 according to the present disclosure.

As shown in FIG. 2A-1, at least one electronic component 21 and a dam 25 are disposed on a carrier structure 20.

In an embodiment, the carrier structure 20 is, for example, a package substrate with a core layer and a circuit structure, a package substrate with a coreless circuit structure, a through-silicon interposer (TSI) with conductive through-silicon vias (TSVs), or other board types. The carrier structure 20 comprises at least one insulating layer and at least one circuit layer bonded to the insulating layer, such as at least one fan-out type redistribution layer (RDL). It should be understood that the carrier structure 20 can also be other chip-carrying boards, such as a lead frame, a wafer, or other boards with metal routings, but the present disclosure is not limited to as such.

Moreover, the electronic component 21 is an active element, a passive element, or a combination of the active element and the passive element, wherein the active element is such as a semiconductor chip, and the passive element is such as a resistor, a capacitor, or an inductor. In an embodiment, the electronic component 21 is a semiconductor chip and has an active surface 21a and an inactive surface 21b opposing the active surface 21a, and the active surface 21a is disposed on the circuit layer of the carrier structure 20 via a plurality of conductive bumps 210 such as solder materials, metal pillars, or others in a flip-chip manner and electrically connected to the circuit layer, and the conductive bumps 210 are encapsulated by an underfill 211; alternatively, the electronic component 21 can be electrically connected to the circuit layer of the carrier structure 20 via a plurality of bonding wires (not shown) by means of wire bonding; or, the electronic component 21 can be directly in contact with the circuit layer of the carrier structure 20. It should be understood that there are various ways in which the electronic component 21 can be electrically connected to the carrier structure 20 without special limitations.

Furthermore, the dam 25 is made of an insulating material such as a thermally conductive glue material or a non-thermally conductive glue material. The dam 25 is of a wall structure and surrounds four side surfaces 21c of the electronic component 21, as shown in FIG. 2A-2. For instance, the dam 25 is a heat-resistant colloid made of such as silicon glue/silicone material or ultraviolet (UV) glue such as acrylic material, such that the dam 25 is formed by dispensing glue and has a continuous frame.

Additionally, a height H2 of the dam 25 relative to the carrier structure 20 is greater than a height H1 of the electronic component 21 relative to the carrier structure 20.

As shown in FIG. 2B, a bonding layer 24 made of such as a glue material is formed on the carrier structure 20, such that the bonding layer 24 is located at the outer periphery of the dam 25.

As shown in FIG. 2C, a thermal conduction layer 22 is formed on the electronic component 21, such that the electronic component 21 and the underfill 211 are encapsulated by the thermal conduction layer 22.

In an embodiment, the thermal conduction layer 22 is served as a thermal interface material (TIM). For instance, the thermal conduction layer 22 can be made of liquid metal and has high thermal conductivity. Further, the liquid metal is pure without containing a glue material such as a solder material.

Besides, the thermal conduction layer 22 is in contact with and bonded to the inactive surface 21b and the side surfaces 21c of the electronic component 21 and the underfill 211.

Therefore, the dam 25 is used to limit the flow range of the thermal conduction layer 22 (the liquid metal) to prevent the liquid metal from overflowing.

As shown in FIG. 2D, a heat sink 23 is disposed on the bonding layer 24 of the carrier structure 20 to cover the electronic component 21, the dam 25 and the thermal conduction layer 22. Then the bonding layer 24 is cured, so that the heat sink 23 is fixed on the carrier structure 20.

In an embodiment, the heat sink 23 has a heat dissipation body 230 that is in contact with and bonded to the thermal conduction layer 22 and the dam 25, and the heat sink 23 has a plurality of supporting legs 231 extending downward from edges of the heat dissipation body 230 to bond with the bonding layer 24, so that the dam 25 is located between the supporting legs 231 and the electronic component 21. The heat dissipation body 230 is of a heat sink type, and a lower side of the heat dissipation body 230 is pressed against the dam 25 and the thermal conduction layer 22 (i.e., the liquid metal), such that the thermal conduction layer 22 (i.e., the liquid metal) is located between the heat dissipation body 230 and the electronic component 21. For instance, the heat sink 23 is a metal structure such as a copper frame, and the heat dissipation body 230 and the supporting legs 231 are integrally formed.

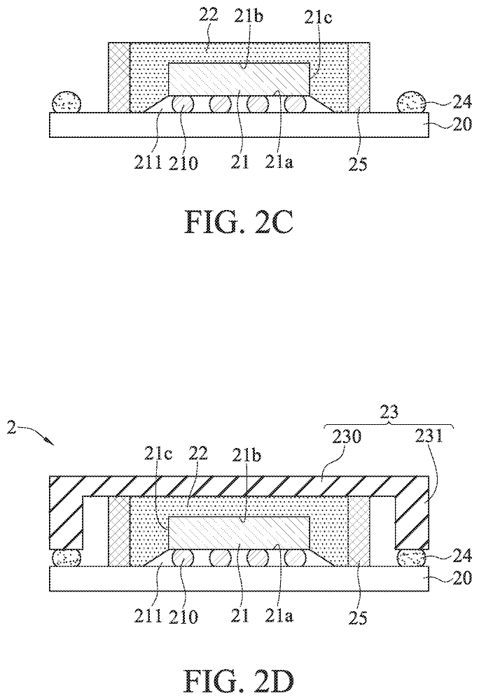

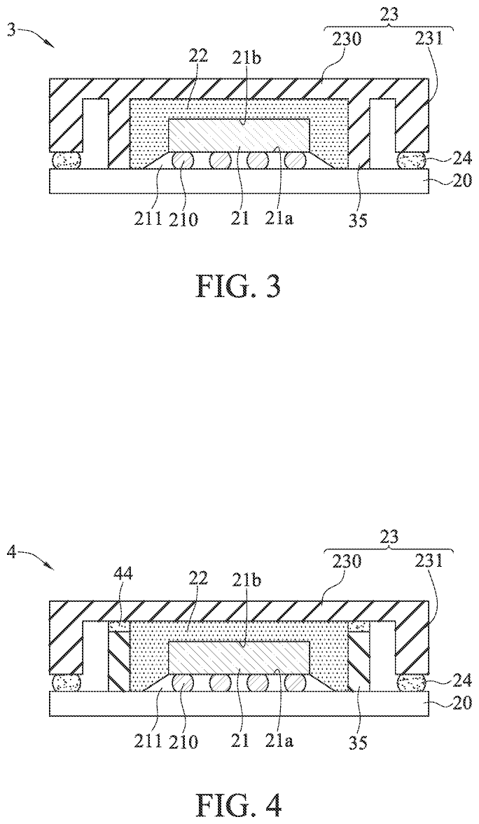

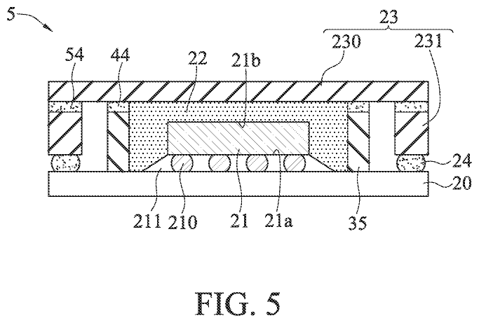

In addition, in an electronic package 3 of FIG. 3, a dam 35 can also be made of metal material and is integrally formed with the heat sink 23, that is, the dam 35 is a wall structure extending downward from the heat dissipation body 230. Alternatively, in an electronic package 4 of FIG. 4, the dam 35 of the metal wall structure can be bonded onto the heat dissipation body 230 of the heat sink 23 via an adhesive material 44 such as a glue material. It should be understood that in an electronic package 5 of FIG. 5, the supporting legs 231 can also be bonded onto the heat dissipation body 230 of the heat sink 23 via an adhesive material 54 such as a glue material.

Moreover, a plurality of conductive components (not shown) can be disposed on the lower side of the carrier structure 20 according to requirements, and the conductive components can be metal pillars such as copper pillars, metal bumps covered with insulating blocks, solder balls, solder balls with copper core balls, or other conductive structures and can be used for the electronic package 2, 3, 4, 5 to be connected to an electronic device (not shown) such as a circuit board.

Therefore, in the manufacturing method of the electronic package 2, 3, 4, 5 of the present disclosure, the arrangement of the dam 25, 35 can strongly support the heat sink 23, so that the thermal stress can be effectively dispersed, thereby controlling the deformation (the warpage) of the electronic component 21 and/or the heat dissipation body 230. Hence, compared to the prior art, the electronic package 2, 3, 4, 5 of the present disclosure not only can meet the requirements of thinning and increasing board area, but also can prevent the electronic component 21 or the heat sink 23 from excessive warping due to stress concentration, so as to prevent the problem of delamination from occurring between the electronic component 21 (and/or the heat dissipation body 230) and the thermal conduction layer 22.

Furthermore, when the thermal conduction layer 22 is a liquid metal, its high thermal conductivity can improve the heat transfer efficiency of the electronic component 21. Further, by the characteristic of the large surface tension of the liquid metal, the dam 25 can constrain the flow of the liquid metal on the surfaces of the electronic component 21 (such as the inactive surface 21b and the side surfaces 21c), so that the liquid metal can be adhered on the electronic component 21. Hence, compared to the prior art, the electronic package 2, 3, 4, 5 of the present disclosure has better heat dissipation effect.

In addition, since the dam 25 is much closer to the periphery of the electronic component 21 than the supporting legs 231, so when the thickness of the electronic package 2, 3, 4, 5 is thinned and the area of the electronic package 2, 3, 4, 5 is getting larger and larger, the arrangement of the dam 25 can reduce the extent of the warpage of the electronic package 2, 3, 4, 5 compared to the conventional semiconductor packages and reduce the surface peeling stress of the electronic component 21. Therefore, the dam 25 can provide a binding force to maintain the distance between the center of the heat dissipation body 230 and the carrier structure 20, thereby preventing delamination from occurring between the heat dissipation body 230 and the thermal conduction layer 22, so that the thermal conduction effect and the reliability of products can both be improved.

The present disclosure further provides an electronic package 2, 3, 4, 5, which comprises: a carrier structure 20, at least one electronic component 21 disposed on the carrier structure 20, a dam 25, 35 disposed on the carrier structure 20 and surrounding the electronic component 21, a thermal conduction layer 22 encapsulating the electronic component 21, and a heat sink 23 disposed on the carrier structure 20.

An inactive surface 21b of the electronic component 21, the dam 25, 35 and the thermal conduction layer 22 are covered by the heat sink 23.

The thermal conduction layer 22 is located between side surfaces 21c of the electronic component 21 and the dam 25, 35 and is located between the heat sink 23 and the inactive surface 21b of the electronic component 21.

In an embodiment, the dam 25, 35 is a wall structure.

In an embodiment, the dam 25, 35 is a frame.

In an embodiment, the dam 25, 35 is made of an insulating material or a metal material.

In an embodiment, the dam 35 and the heat sink 23 are integrally formed.

In an embodiment, the dam 35 is bonded to the heat sink 23 via an adhesive material 44.

In an embodiment, the thermal conduction layer 22 is made of a liquid metal.

In an embodiment, the heat sink 23 has a heat dissipation body 230 bonded to the thermal conduction layer 22 and the dam 25, 35 and has a plurality of supporting legs 231 disposed on the heat dissipation body 230 and bonded to the carrier structure 20. For instance, the heat dissipation body 230 and the supporting legs 231 are integrally formed. Alternatively, the heat dissipation body 230 is bonded to the supporting legs 231 via an adhesive material 54.

To sum up, in the electronic package and the manufacturing method thereof according to the present disclosure, the arrangement of the dam can strongly support the heat sink, so that the thermal stress can be effectively dispersed, thereby effectively controlling the deformation (the warpage) of the electronic component and/or the heat dissipation body. Hence, the electronic package of the present disclosure not only can meet the requirements of thinning and increasing board area, but also can prevent the electronic component or the heat sink from excessive warping due to stress concentration, so as to prevent the problem of delamination from occurring between the electronic component (and/or the heat dissipation body) and the thermal conduction layer.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic component disposed on the carrier structure;
a dam disposed on the carrier structure and surrounding the electronic component;
a thermal conduction layer encapsulating the electronic component and located between the electronic component and the dam; and
a heat sink disposed on the carrier structure and covering the electronic component, the dam and the thermal conduction layer, wherein the thermal conduction layer is further located between the heat sink and the electronic component.

2. The electronic package of claim 1, wherein the dam is a frame or a wall structure.

3. The electronic package of claim 1, wherein the dam is made of an insulating material or a metal material.

4. The electronic package of claim 1, wherein the dam and the heat sink are integrally formed.

5. The electronic package of claim 1, wherein the dam is bonded to the heat sink via an adhesive material.

6. The electronic package of claim 1, wherein the thermal conduction layer is made of a liquid metal.

7. The electronic package of claim 1, wherein the heat sink has a heat dissipation body bonded to the thermal conduction layer and the dam and has a plurality of supporting legs disposed on the heat dissipation body and bonded to the carrier structure.

8. The electronic package of claim 7, wherein the heat dissipation body and the supporting legs are integrally formed.

9. The electronic package of claim 7, wherein the heat dissipation body is bonded to the supporting legs via an adhesive material.

10. A method of manufacturing an electronic package, the method comprising:
disposing an electronic component on a carrier structure;
disposing a dam on the carrier structure;
encapsulating the electronic component by a thermal conduction layer; and
disposing a heat sink on the carrier structure to cover the electronic component, the dam and the thermal conduction layer, wherein the electronic component is surrounded by the dam, and the thermal conduction layer is located between the electronic component and the dam and between the heat sink and the electronic component.

11. The method of claim 10, wherein the dam is a frame or a wall structure.

12. The method of claim 10, wherein the dam is made of an insulating material or a metal material.

13. The method of claim 10, wherein the dam and the heat sink are integrally formed.

14. The method of claim 10, wherein the dam is bonded to the heat sink via an adhesive material.

15. The method of claim 10, wherein the thermal conduction layer is made of a liquid metal.

16. The method of claim 10, wherein the heat sink has a heat dissipation body bonded to the thermal conduction layer and the dam and has a plurality of supporting legs disposed on the heat dissipation body and bonded to the carrier structure.

17. The method of claim 16, wherein the heat dissipation body and the supporting legs are integrally formed.

18. The method of claim 16, wherein the heat dissipation body is bonded to the supporting legs via an adhesive material.
